(19) United States
(12) Patent Application Publication
(10) Pub. No.: US 2026/0215134 A1
(43) Pub. Date: Jul. 23, 2026

(54) ELECTRONIC DEVICE INCLUDING DISPLAY DEVICE AND FRAME

(71) Applicant: SAMSUNG DISPLAY CO., LTD., YONGIN-SI (KR)

(72) Inventor: HONGAM KIM, Yongin-si (KR)

(21) Appl. No.: 19/444,798

(22) Filed: Jan. 9, 2026

(30) Foreign Application Priority Data
Jan. 17, 2025 (KR) 10-2025-0007231

(51) Int. Cl. H10K 59/80

(52) U.S. Cl. CPC H10K 59/873

(57) ABSTRACT

An electronic device includes a display device and a frame accommodating the display device. The display device includes a lower plate, a display panel, a glass layer, and a window protection layer sequentially stacked in a first direction. The frame includes an extension part disposed along an outer periphery of the display device and extending in the first direction, and a protrusion part protruding from the extension part in a second direction crossing the first direction. A first separation distance is measured between the protrusion part and the lower plate in the second direction. A second separation distance is measured between the extension part and the window protection layer in the second direction. A ratio of the second separation distance to the first separation distance is about 0.8 to about 1.2.

### CROSS-REFERENCE TO RELATED APPLICATION

This non-provisional patent application claims priority under 35 U.S.C. §119 to Korean Patent Application No. 10-2025-0007231, filed on January 17, 2025, in the Korean Intellectual Property Office, the disclosure of which is incorporated by reference herein in its entirety.

### Technical Field

Embodiments of the present disclosure relate to an electronic device including a display device and a frame.

### Discussion of the Related Art

Recently, various types of flat panel display devices, which are lightweighted and compact, have been developed. Flat panel display devices include liquid crystal display (LCD) devices, field emission display (FED) devices, plasma display panels (PDP), and organic light-emitting diode (OLED) display devices. Among these, an OLED display device has emerged as a candidate dues to the foldable and flexible properties, in which new structural approaches for durability and aesthetic integration with device frames may be needed.

Among the flat panel displays, OLED devices display images by using organic light-emitting diodes, which emit light through recombination of electrons and holes. Such OLED devices have attracted attention as next-generation displays due to the fast response speeds and low power consumption. In some cases, these OLED display devices are suitable for integration into foldable and flexible display architectures that require enhanced structural resilience and improved aesthetic finish.

### SUMMARY

The disclosure provides a display device with improved aesthetics and stability and an electronic device including the display device.

An embodiment of the present disclosure provide an electronic device including a display device and a frame accommodating the display device. The display device includes a lower plate, a display panel disposed on the lower plate, a glass layer disposed on the display panel, and a window protection layer disposed on the glass layer. The lower plate, the display panel, the glass layer, and the window protection layer are sequentially stacked in a first direction. The frame includes an extension part disposed along an outer periphery of the display device and extending in the first direction, and a protrusion part protruding from the extension part in a second direction crossing the first direction. A first separation distance is measured between the protrusion part and the lower plate in the second direction. A second separation distance is measured between the extension part and the window protection layer in the second direction. A ratio of the second separation distance to the first separation distance is about 0.8 to about 1.2.

In an embodiment, the electronic device may further include a first cover layer disposed between the glass layer and the window protection layer and extending in the second direction, and the first cover layer may include a first folded part folded toward the glass layer.

In an embodiment, the first cover layer may further include a second folded part extending from the first folded part toward a bottom surface of the glass layer and covers at least a portion of the bottom surface of the glass layer.

In an embodiment, the electronic device may further include a second cover layer disposed on and covering at least a portion of a bottom surface of the glass layer.

In an embodiment, the second cover layer may include at least one of a black resin, a carbon black resin, an organic light absorber, a silica composite resin, or a black polyimide resin.

In an embodiment, the second cover layer may be spaced apart from the protrusion part of the frame in the first direction.

In an embodiment, a first separation distance between the bottom surface of the glass layer and the protrusion part of the frame may be about 0.025 mm to about 0.1 mm.

In an embodiment, a second distance is measured between second cover layer and an upper surface of the protrusion part of the frame, and a ratio of the first distance and the second distance may be about 0.25 to about 0.8.

In an embodiment, the second separation distance may be about 0.3 mm to about 0.7 mm.

In an embodiment, the first separation distance may be equal to the second separation distance.

An electronic device including a display device and a frame accommodating the display device. The display device includes a display panel, a glass layer disposed on the display panel, a first cover layer disposed on the glass layer, and a window protection layer disposed on the first cover layer. The display panel, the glass layer, the first cover layer, and the window protection layer are sequentially stacked in a first direction and extend in a second direction crossing the first direction. The frame includes an extension part disposed along an outer periphery of the display device and extending in the first direction, and a protrusion part protruding from the extension part in the second direction. The glass layer and the window protection layer further extend toward the extension part and are spaced apart from the protrusion part in the first direction, and the window protection layer is spaced apart from the extension part in the second direction.

In an embodiment, an extension length of the window protection layer may be about 0.8 mm to about 1.5 mm.

In an embodiment, a first separation distance between the window protection layer and the extension part of the frame may be about 0.3 mm to about 0.7 mm.

In an embodiment, the electronic device may further include a lower plate supporting the display panel, and the lower plate may be spaced apart from the protrusion part of the frame in the second direction. In an embodiment, a second separation distance is measured between the protrusion part and the lower plate in the second direction, and a ratio of the first separation distance to the second separation distance may be about 0.8 to about 1.2.

In an embodiment, the electronic device may further include a panel protection film disposed between the display panel and the lower plate.

In an embodiment, the electronic device may further include a second cover layer disposed on and covering at least a portion of a bottom surface of the glass layer.

In an embodiment, the second cover layer may be spaced apart from the protrusion part of the frame in the first direction. In an embodiment, the first cover layer may include a first folded part folded toward the glass layer, and a second folded part folded from the first folded part toward a bottom surface of the glass layer and covers at least a portion of the bottom surface of the glass layer.

An electronic device including a display device and a frame accommodating the display device. The display device includes a lower plate, a display panel disposed on the lower plate, and a window protection layer disposed on the lower plate. The lower plate, the display panel, and the window protection layer are sequentially stacked in a first direction. The frame includes an extension part disposed along an outer periphery of the display device and extending in the first direction, and a protrusion part protruding from the extension part in a second direction crossing the first direction. A first separation distance is measured between the protrusion part and the lower plate in the second direction. A second separation distance is measured between the extension part and the window protection layer in the second direction. A ratio of the second separation distance to the first separation distance is about 0.8 to about 1.2. The second separation distance is about 0.3 mm to about 0.7 mm.

### BRIEF DESCRIPTION OF THE DRAWINGS

The accompanying drawings attached to the present disclosure illustrate example embodiments of the present disclosure, and are provided to understand the technical idea of the present disclosure, together with the description of the scope of the present disclosure to be provided later, and therefore, it should not necessarily be construed as limited to the matter shown in the accompanying drawings in which:

FIG. 1 is a perspective view schematically illustrating an example of an electronic device according to an embodiment of the disclosure;

FIG. 2 is a plan view schematically illustrating an example of a display device according to an embodiment of the disclosure;

FIG. 3 is a perspective view schematically illustrating the folded configuration of the display device of FIG. 2;

FIG. 4 is a block diagram schematically illustrating the structure of the display device of FIG. 2;

FIG. 5 is a circuit diagram illustrating an example of an equivalent circuit of a sub-pixel of the display device of FIG. 2;

FIG. 6 is a cross-sectional view schematically illustrating an example of the cross-section of the display device taken along a line A-A' of FIG. 2;

FIG. 7 is a cross-sectional view schematically illustrating an example of the cross-section of the display device taken along a line B-B' of FIG. 1;

FIG. 8 is a cross-sectional view schematically illustrating an example of the cross-section of the display device taken along a line E-E' of FIG. 1;

FIG. 9 is a cross-sectional view schematically illustrating an example of the cross-section of the display device taken along a line B-B' of FIG. 1;

FIG. 10 is a cross-sectional view schematically illustrating an example of the cross-section of the display device taken along a line B-B' of FIG. 1;

FIG. 11 is a block diagram of an electronic device according to an embodiment; and

FIG. 12 is a schematic diagram of an electronic device according to various embodiments.

### DETAILED DESCRIPTION

As the disclosure may include various changes and numerous embodiments, particular embodiments are illustrated in the drawings and described in detail in the detailed description. Effects and features of the disclosure and methods of achieving the same may be apparent with reference to embodiments and drawings described below in detail. However, the disclosure is not necessarily limited to the illustrated embodiments and may be implemented in various other forms without departing from the spirit or scope of the invention.

In the following embodiments, while such terms as "first," "second," etc., may be used to describe various elements, such elements are not necessarily limited to the above terms. Therefore, in some cases, the first component mentioned below may be the second component within the technical idea of the present invention.

In the following embodiments, an expression used in the singular encompasses the expression of the plural, unless the expression has a clearly different meaning in the context. For example, the terms “a”, “an”, “the”, or the like may indicate one or more elements.

In the following embodiments, it is to be understood that the terms such as "including" and "having" are intended to indicate the existence of the features, or elements disclosed in the disclosure, and are not necessarily intended to preclude the possibility that one or more other features or elements may exist or may be added.

It will be understood that when a layer, region, or element is referred to as being formed on another layer, region, or element, the layer, region, or element can be directly or indirectly formed on the other layer, region, or element. For example, intervening layers, regions, or elements may be present between the layers, regions, or elements, respectively.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

The disclosure is described more fully with reference to the accompanying drawings, in which embodiments of the disclosure are shown. Like reference numerals in the drawings denote like elements. For example, same reference numerals may refer to the same components throughout the disclosure and the figures. The shapes, sizes, ratios, angles, numbers, etc. disclosed in the drawings for explaining the embodiments are exemplary, and therefore the present invention is not necessarily limited to the matters illustrated. To the extent that an element is not described in detail with respect to a figure, it may be understood that the element is at least similar to a corresponding element that has been described elsewhere within the present disclosure.

Embodiments of the present disclosure relate to an electronic device including a display device and a surrounding frame structure configured to enhance durability, aesthetic integration, and structural integrity without a separate protective member. The display device includes a lower plate, a display panel, a glass layer, and a window protection layer, sequentially disposed in a first direction. A frame accommodates the display device and includes an extension part positioned along an outer periphery of the display device and extending in the first direction, and a protrusion part protruding from the extension part in a second direction crossing (or perpendicular to) the first direction.

In one aspect, a first separation distance is formed between the protrusion part and the lower plate in the second direction, and a second separation distance is formed between the extension part and the window protection layer in the second direction. The ratio of the second separation distance to the first separation distance ranges from about 0.8 to about 1.2. This spatial configuration enables effective distribution of impact force when external mechanical stress is applied to the frame region, thereby reducing the damages to the internal layers of the display device and enhancing overall structural robustness.

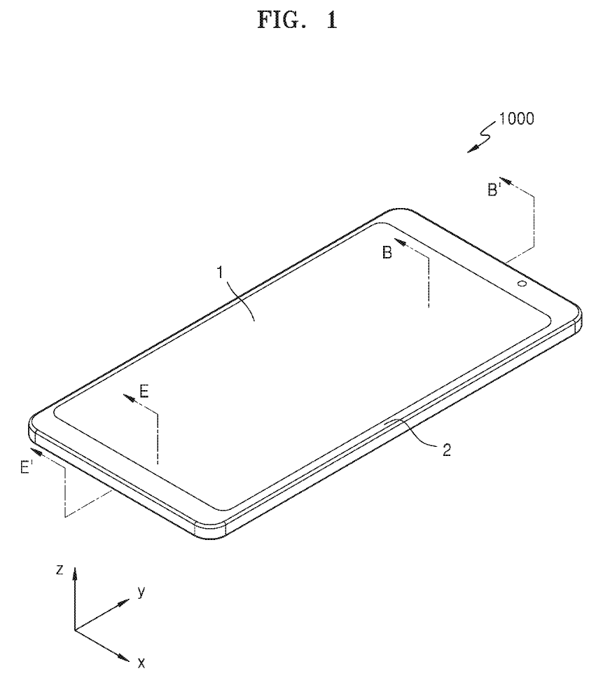

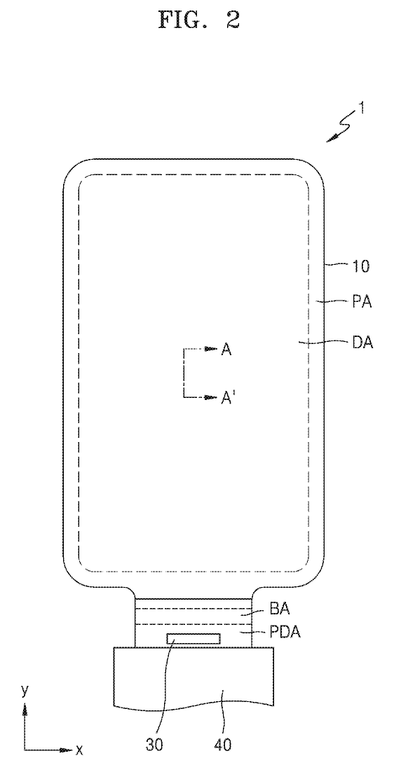

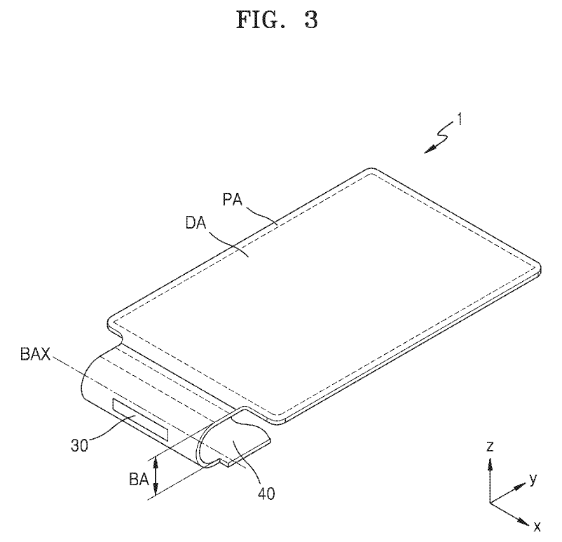

FIG. 1 is a perspective view schematically illustrating an example of an electronic device according to an embodiment of the disclosure, FIG. 2 is a plan view schematically illustrating an example of a display device according to an embodiment of the disclosure, and FIG. 3 is a perspective view schematically illustrating the folded configuration of the display device of FIG. 2.

In the specification, a ‘first direction z’ may be a stacking direction of the components of a display device 1 to be described below. In addition, a 'second direction y' may be a longitudinal direction of an electronic device 1000, and a 'third direction x' may be a width direction of the electronic device 1000 or a direction parallel to a bending axis BAX to be described below. The 'third direction x' may be a direction perpendicular to both the first direction z and the second direction y. In one aspect, the first direction z, the second direction y, and the third direction x may be directions perpendicular to each other.

Referring to FIGS. 1 to 3, the electronic device 1000 may include the display device 1 and a frame 2 positioned along and surrounding the outer periphery of the display device 1. The frame 2 may accommodate and support the display device 1. As the frame 2 is disposed on the outer periphery of the display device 1 to surround the edges of the display device 1, the frame 2 may protect the display device 1 from external impact and prevent the display screen of the display device 1 from being broken. For example, the frame 2 may increase the strength of the electronic device 1000 and protect the display device 1, a processor, a memory, a power module, or other electronic components included in the electronic device 1000 from external impact.

In some embodiments, the frame 2 may prevent foreign materials, such as moisture and dust, from penetrating into the display device 1 by sealing the display device 1.

In some embodiments, the frame 2 may disperse heat generated during an operation of the electronic device 1000. In some aspects, the frame 2 may enhance the aesthetics of the electronic device 1000 by being smoothly connected to the display device 1. In some cases, the frame 2 may eliminate the need for other sealing components or adhesive elements to connect the electronic device 1000 with the display device 1.

According to some embodiments, the frame 2 may include a material that is corrosion-resistant, lightweight, and durable. For example, the frame 2 may include at least one of an aluminum alloy, stainless steel, thermoplastic plastic, such as polycarbonate and acrylonitrile butadiene styrene, titanium, or a ceramic.

In some embodiments, the display device 1 may display moving images or still images, and may display a screen on a display panel 10 or perform input and output of data. The display device 1 may be a portable electronic device, such as a mobile phone, a smartphone, a table computer, a mobile communication terminal, an electronic notebook, an electronic book, a portable multimedia player (PMP), a navigation device, an Ultra Mobile PC (UMPC), or other handheld computing devices. The display device may also be used as a display screen of various electronic devices 1000, such as a television, a laptop/notebook personal computer (PC), a computer monitor, an advertisement board, or an Internet of things (IoT) device. In some cases, for example, the IoT may include smart appliances, home hubs, and industrial sensors.

In some embodiments, the display device 1 may be used in the electronic device 1000, such as a wearable device. Examples of wearable devices include a smart watch, a watch phone, a glasses-type display, and a head-mounted display (HMD).

In some embodiments, the display device 1 may be used as a display in vehicle-mounted electronic systems, such as a dashboard, a center fascia or a center information display (CID) disposed on a dashboard, a room mirror display replacing a side mirror of a vehicle, and a display screen disposed on a back surface of a front seat as entertainment for a passenger in a back seat of a vehicle.

The display device 1 of the disclosure may include a display area DA in which a plurality of pixels are positioned, and a peripheral area PA disposed outside the display area DA. In some embodiments, the peripheral area PA may include a pad area PDA, which is located on one side of the display area DA and is an area to which various types of electronic components, such as an integrated circuit 30 and/or a flexible circuit board 40, are electrically attached, and a bending area BA between the display area DA and the pad area PDA. The display area DA, the peripheral area PA, the pad area PDA, and the bending area BA may be defined on a substrate.

FIG. 2 is a plan view illustrating the shape of a substrate or similar structural layer during the manufacturing process of the display device 1, the bending area BA may be bent based on the bending axis BAX extending in a third direction x, as shown in FIG. 3. The bending direction is set so that the pad area PDA is located behind the display area DA. Accordingly, the area of the peripheral area PA, which is recognized by the user, may be reduced.

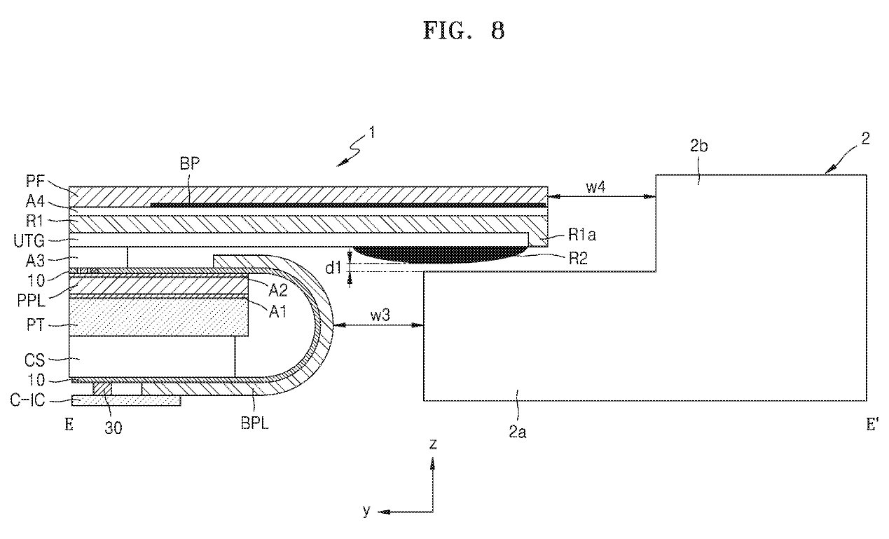

A circuit cover (C-IC of FIG. 8) may be attached to the integrated circuit 30 and the flexible circuit board 40 in the pad area PDA. The circuit cover C-IC may protect the integrated circuit 30 and the flexible circuit board 40 from mechanical impact. In some cases, the circuit cover C-IC may also provide waterproofing and electrical insulation functions to the integrated circuit 30 and the flexible circuit board 40.

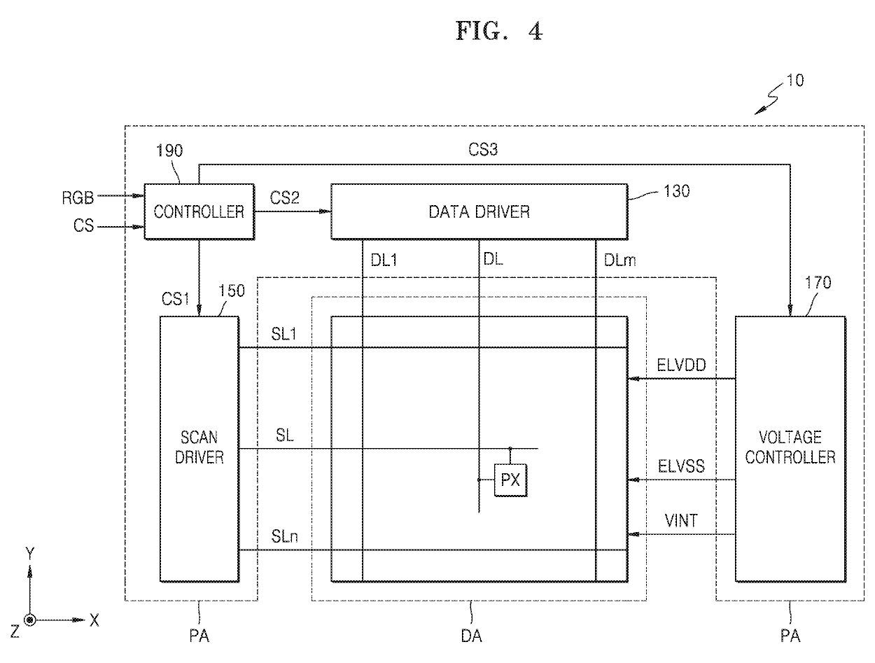

FIG. 4 is a block diagram schematically illustrating the structure of the display device of FIG. 2. The example, shown in FIG. 4 includes the display panel 10, a data driver 130, a scan driver 150, a voltage controller 170, and a controller 190.

Referring to FIG. 4, a plurality of scan lines SL1, ..., and SLn extending in the third direction x, a plurality of data lines DL1, ..., and DLm extending in a second direction y, which perpendicularly intersects the third direction x, and a plurality of sub-pixels PX may be disposed in the display area DA. In one aspect, each of m and n is a natural number (e.g., integer). For example, m and n each represent natural numbers indicating the total number of data lines and scan lines, respectively.

Electrical signals may be applied to the plurality of sub-pixels PX via the plurality of scan lines SL1, ..., and SLn, the plurality of data lines DL1, ..., and DLm, or other lines. In some cases, for example, the plurality of scan lines SL1, ..., and SLn may be arranged in a plurality of rows extending in the third direction x and configured to transmit scan signals to the plurality of sub-pixels PX. In some cases, for example, the plurality of data lines DL1, ..., and DLm may be arranged in a plurality of columns extending in the second direction y and configured to transmit data signals to the plurality of sub-pixels PX. The plurality of sub-pixels PX may be disposed at intersection portions of the plurality of scan lines SL1, ..., and SLn and the plurality of data lines DL1, ..., and DLm.

Each sub-pixel PX may emit, for example, red, green, blue, or white light by including a light-emitting element. For example, each sub-pixel PX may include, but is not necessarily limited to, an organic light-emitting diode (OLED) as a light-emitting element.

A data driver 130 that provides data signals to the display area DA, a scan driver 150 that provides scan signals to the display area DA, a voltage controller 170 that controls voltages supplied to the display area DA, and a controller 190 may be arranged in the peripheral area PA. For example, controller 190 may be configured to control the data driver 130, the scan driver 150, and the voltage controller 170.

The voltage controller 170 may generate and control a first voltage ELVDD, a second voltage ELVSS, and an initialization voltage VINT, which are provided to the display area DA.

The first voltage ELVDD, the second voltage ELVSS, and the initialization voltage VINT may be applied to the plurality of sub-pixels PX. For example, the first voltage ELVDD may be a positive voltage, and the second voltage ELVSS may be a negative voltage or a ground voltage. For example, the second voltage ELVSS may have a lower level than the first voltage ELVDD.

The controller 190 may receive image signals RGB and control signals CS from an external source (for example, a system board). The controller 190 may generate image data by converting the data format of the image signals RGB to match the interface specifications of the data driver 130. The controller 190 may provide, to the data driver 130, the image data DATA after data formats have been converted.

The controller 190 may generate and output a first control signal CS1 and a second control signal CS2 in response to the control signals CS received from the external source. The first control signal CS1 may be defined as a scan control signal, and the second control signal CS2 may be defined as a data control signal. The first control signal CS1 may be provided to the scan driver 150. The second control signal CS2 may be provided to the data driver 130. Additionally, the controller 190 may generate a third control signal CS3, where the third control signal CS3 may be provided to the voltage controller 170 and may be used to control timing, enable/disable behavior, or voltage level adjustment for voltages such as ELVDD, ELVSS, and VINT.

The scan driver 150 may generate a plurality of scan signals in response to the first control signal CS1. The plurality of scan signals may be applied to the plurality of sub-pixels PX through the plurality of scan lines SL1, ..., and SLn.

The data driver 130 may generate a plurality of data voltages corresponding to the image data DATA, in response to (or based on) the second control signal CS2. The plurality of data voltages may be applied to the plurality of sub-pixels PX through the plurality of data lines DL1, ..., and DLm. The data driver bmay simultaneously provide the data voltages generated in units of sub-pixel rows to the plurality of sub-pixels PX via the plurality of data lines DL1, ..., and DLm.

The plurality of sub-pixels PX may receive the plurality of data voltages in response to the plurality of scan signals, respectively. For example, each sub-pixel PX may receive a corresponding data voltage. The plurality of sub-pixels PX may display an image by emitting light having brightnesses corresponding to the plurality of data voltages. The plurality of sub-pixels PX may display the image by emitting light sequentially or simultaneously.

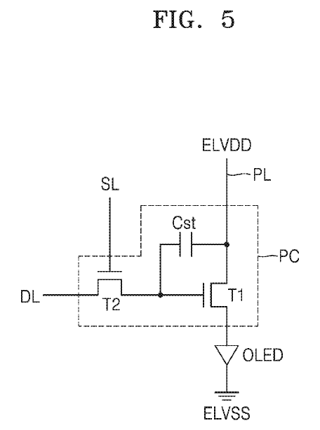

FIG. 5 is a circuit diagram illustrating an example of an equivalent circuit of a sub-pixel of the display device of FIG. 2.

Referring to FIG. 5, a pixel circuit PC may be connected to a display element, for example, an organic light-emitting diode OLED. The pixel circuit PC may be arranged in the display area DA. The pixel circuit PC may include a driving thin-film transistor T1, a switching thin-film transistor T2, and a storage capacitor Cst. For example, the organic light-emitting diode OLED may emit red, green, or blue light, or may emit red, green, blue, or white light.

The switching thin-film transistor T2 may be connected to a scan line SL and a data line DL, and be configured to transmit, to the driving thin-film transistor T1, a data signal or a data voltage input from the data line DL based on a scan signal or a switching voltage input from the scan line SL. The storage capacitor Cst may be connected to the switching thin-film transistor T2 and a driving voltage line PL, and may store a voltage corresponding to the difference between a voltage received from the switching thin-film transistor T2 and the first voltage ELVDD supplied to the driving voltage line PL.

The driving thin-film transistor T1 may be connected to the driving voltage line PL and the storage capacitor Cst, and may control a driving current flowing from the driving voltage line PL to the organic light-emitting diode OLED based on a voltage value stored in the storage capacitor Cst. The organic light-emitting diode OLED may emit light having a brightness corresponding to the driving current. An opposite electrode of the organic light-emitting diode OLED may receive the second voltage ELVSS.

Although FIG. 5 illustrates that the pixel circuit PC includes two thin-film transistors and one storage capacitor, the pixel circuit PC may include at least three thin-film transistors, and/or the pixel circuit PC may include at least two capacitors. The number and arrangement of circuit components in the pixel circuit PC may vary based on a target resolution, color accuracy, or power optimization requirements.

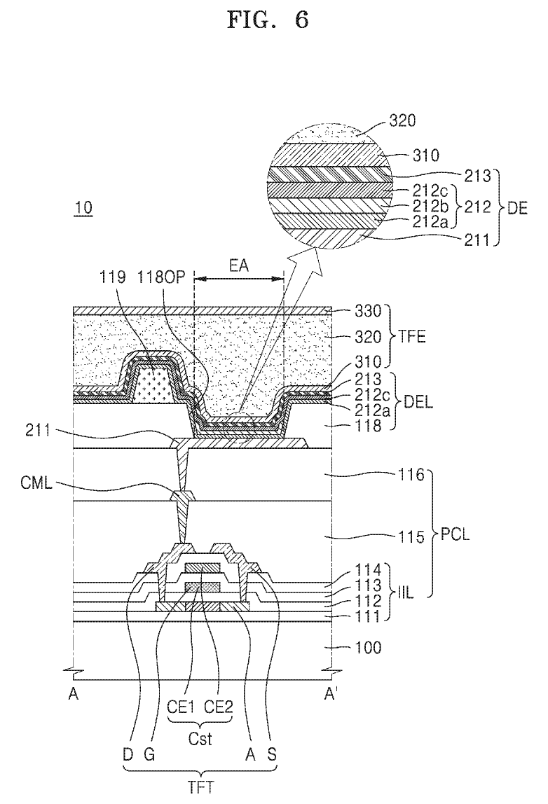

FIG. 6 is a cross-sectional view schematically illustrating an example of the cross-section of the display device taken along a line A-A' of FIG. 2.

Referring to FIG. 6, the display device 1 may include the display panel 10. In some embodiments, the display panel 10 may include a substrate 100, a buffer layer 111, a pixel circuit layer PCL, a display element layer DEL, and a thin-film encapsulation layer TFE.

The substrate 100 may include a transparent glass material including SiO₂ as a main compound. However, the disclosure is not necessarily limited to thereto. For example, the substrate 100 may also include a transparent plastic material. The plastic material may include polyethersulfone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose triacetate (TAC), cellulose acetate propionate (CAP), or other plastic materials. In an embodiment, the substrate 100 may have a multi-layered structure including a base layer and a barrier layer, the base layer including one or more plastic materials described above. The substrate 100 including the plastic material may be flexible, rollable, and bendable.

The buffer layer 111 may be disposed on the substrate 100. The buffer layer 111 may include an inorganic insulating material such as silicon nitride, silicon oxynitride, or silicon oxide. The buffer layer 111 may include a single layer or a multi-layer, each including the inorganic insulating material stated above.

The pixel circuit layer PCL may be disposed on the buffer layer 111. The pixel circuit layer PCL may include a thin-film transistor TFT included in a pixel circuit, an inorganic insulating layer IIL, a first planarization layer 115, and a second planarization layer 116, where the inorganic insulating layer IIL, the first planarization layer 115, and the second planarization layer 116 are disposed below components of the thin-film transistor TFT. In some cases, the inorganic insulating layer IIL, the first planarization layer 115, and the second planarization layer 116 may be sequentially stacked. The inorganic insulating layer IIL may include the buffer layer 111, a first gate insulating layer 112, a second gate insulating layer 113, and an interlayer insulating layer 114. In some cases, the buffer layer 111, the first gate insulating layer 112, the second gate insulating layer 113, and the interlayer insulating layer 114 may be sequentially stacked.

The thin-film transistor TFT may include a semiconductor layer A, and the semiconductor layer A may include polysilicon. Alternatively, the semiconductor layer A may include amorphous silicon, an oxide semiconductor, or an organic semiconductor. The semiconductor layer A may include a channel area, a drain area, and a source area, where the drain area and the source area are respectively disposed on respective sides of the channel area. For example, the channel area may be disposed between the drain area and the source area. A gate electrode G may overlap the channel area of the semiconductor layer A.

The gate electrode G may include a low-resistance metal material. The gate electrode G may include a conductive material including molybdenum (Mo), aluminum (Al), copper (Cu), titanium (Ti), or other conductive materials. In some cases, and the gate electrode G may include a multi-layer or a single layer, each including one or more of the aforementioned conductive materials.

The first gate insulating layer 112, disposed between the semiconductor layer A and the gate electrode G, may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), zinc oxide (ZnO_{X}), or other inorganic insulating materials. The zinc oxide (ZnO_{X}) may be zinc oxide (ZnO) and/or zinc peroxide (ZnO₂).

The second gate insulating layer 113 may be disposed and cover the gate electrode G. Similar to the first gate insulating layer 112, the second gate insulating layer 113 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), zinc oxide (ZnOₓ), or other inorganic insulating materials. The zinc oxide (ZnO_{X}) may be zinc oxide (ZnO) and/or zinc peroxide (ZnO₂).

An upper electrode CE2 of a storage capacitor Cst may be disposed on the second gate insulating layer 113. The upper electrode CE2 may overlap the gate electrode G disposed below the upper electrode CE2. The gate electrode G and the upper electrode CE2, which overlap each other with the second gate insulating layer 113, may form the storage capacitor Cst, the second gate insulating layer 113 being disposed between the gate electrode G and the upper electrode CE2. For example, the gate electrode G may function as a lower electrode CE1 of the storage capacitor Cst. In some aspects, the second gate insulating layer 113 may serve as a dielectric layer between the lower electrode CE1 and the upper electrode CE2. Thus, the storage capacitor Cst and the thin-film transistor TFT may be formed to overlap each other. However, the disclosure is not necessarily limited thereto. In some embodiments, the storage capacitor Cst might not overlap the thin-film transistor TFT.

The upper electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). The upper electrode CE2 may include a single layer or a multi-layer, each including one or more of the material stated above.

The interlayer insulating layer 114 may cover the upper electrode CE2. The interlayer insulating layer 114 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), zinc oxide (ZnOₓ), or other inorganic insulating materials. The zinc oxide (ZnO_{X}) may be zinc oxide (ZnO) and/or zinc peroxide (ZnO₂). The interlayer insulating layer 114 may include a single layer or a multi-layer, each including the inorganic insulating material described above.

A drain electrode D and a source electrode S may each disposed on the interlayer insulating layer 114. The drain electrode D and the source electrode S may each include a material having high conductivity. The drain electrode D and the source electrode S may each include a conductive material including molybdenum (Mo), aluminum (Al), copper (Cu), or titanium (Ti), or other conductive metals. In some cases, the drain electrode D and the source electrode S may include a multi-layer or a single layer, each including one or more of the listed conductive materials. In an embodiment, the drain electrode D and the source electrode S may each have a multi-layered structure of Ti/Al/Ti. The drain electrode D and the source electrode S may penetrate the interlayer insulating layer 114, the second gate insulating layer 113, and the first gate insulating layer 112, and may contact upper surface of the corresponding drain area and source area of the semiconductor layer A.

The first planarization layer 115 may be disposed to cover the drain electrode D and the source electrode S. The first planarization layer 115 may include an organic insulating layer. The first planarization layer 115 may include a general commercial polymer, such as poly(methyl methacrylate) (PMMA) or polystyrene (PS), or a polymer derivative having a phenol group. The first planarization layer 115 may include an organic insulating material, such as an acrylic polymer, an imide polymer, an aryl ether polymer, an amide polymer, a fluorine polymer, a p-xylene polymer, a vinyl alcohol polymer, or a combination thereof. In some cases, the first planarization layer 115 may include a combination of commercial polymer and organic insulating material listed above.

A connection electrode CML may be disposed on the first planarization layer 115. For example, the connection electrode CML may be connected to the drain electrode D or the source electrode S through a contact hole penetrating the first planarization layer 115. The connection electrode CML may include a material having high conductivity. The connection electrode CML may include a conductive material including molybdenum (Mo), aluminum (Al), copper (Cu), or titanium (Ti), and may include a multi-layer or a single layer, each including the above material. In an embodiment, the connection electrode CML may have a multi-layered structure of Ti/Al/Ti.

The second planarization layer 116 may be disposed to cover the connection electrode CML. The second planarization layer 116 may include an organic insulating layer. The second planarization layer 116 may include a general commercial polymer, such as PMMA or PS, a polymer derivative having a phenol group, or an organic insulating material, such as an acrylic polymer, an imide polymer, an aryl ether polymer, an amide polymer, a fluorine polymer, a p-xylene polymer, a vinyl alcohol polymer, or a combination thereof.

The display element layer DEL may be disposed on the pixel circuit layer PCL. The display element layer DEL may include a display element DE. The display element DE may be an OLED. A pixel electrode 211 of the display element DE may be electrically connected to the connection electrode CML through a contact hole in the second planarization layer 116.

The pixel electrode 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), or chromium (Cr), or a compound thereof. In an embodiment, the pixel electrode 211 may further include a film including ITO, IZO, ZnO, or In₂O₃ above/below the reflective film stated above.

A pixel defining layer 118 defining an opening 118OP exposing the central portion of the pixel electrode 211 may be disposed on the pixel electrode 211. The pixel defining layer 118 may include an organic insulating material and/or an inorganic insulating material. The opening 118OP may define an emission area EA of light emitted from the display element DE. For example, the width of the opening 118OP may correspond to the width of the emission area EA of the display element DE. The emission area EA may correspond to a region through which light generated in the emission layer 212b passes upward and exits the display panel 10. The emission area EA may be defined by the opening 118OP of the pixel defining layer 118. The emission area EA may be aligned with the exposed surface of the pixel electrode 211, allowing light to be efficiently emitted through the transparent encapsulation layers.

In an embodiment, the pixel defining layer 118 may include a light-blocking material and may be provided in black. The light-blocking material may include carbon black, carbon nanotubes, a resin or paste including a black dye, metal particles, such as nickel (Ni), aluminum (Al), molybdenum (Mo), and alloys thereof, metal oxide particles (e.g., chromium oxide), metal nitride particles (e.g., chromium nitride), or other metal oxide compounds. In some cases, when the pixel defining layer 118 includes a light-blocking material, reflection of external light by metal structures on a lower portion of the pixel defining layer 118 may be reduced.

A spacer 119 may be disposed on the pixel defining layer 118. The spacer 119 may be configured to prevent damage to the substrate 100 during manufacturing the display device. A mask sheet may be used when manufacturing the display panel 10. For example, the spacer 119 may prevent a defect in which a portion of the substrate 100 is damaged by the mask sheet when the mask sheet enters the opening 118OP in the pixel defining layer 118 or closely contacts the pixel defining layer 118 to deposit a deposition material on the substrate 100.

The spacer 119 may include an organic insulating material such as polyimide. Alternatively, the spacer 119 may include an inorganic insulating material such as silicon nitride or silicon oxide, or may include an organic insulating material and an inorganic insulating material.

In an embodiment, the spacer 119 may include a material different from that of the pixel defining layer 118. In an embodiment, the spacer 119 may include the same material as the pixel defining layer 118. For example, the pixel defining layer 118 and the spacer 119 may be formed together in a mask operation using a halftone mask or a comparable patterning technique.

An intermediate layer 212 may be disposed on the pixel defining layer 118. The intermediate layer 212 may include an emission layer 212b disposed in the opening 118OP in the pixel defining layer 118. The emission layer 212b may include a polymer organic material or a low-molecular-weight organic material, which emits light of a certain color.

A first functional layer 212a and a second functional layer 212c may be respectively disposed below and on the emission layer 212b. The first functional layer 212a may include, for example, a hole transport layer (HTL), or an HTL and a hole injection layer (HIL). The second functional layer 212c, as a component disposed on the emission layer 212b, may be optional. The second functional layer 212c may include an electron transport layer (ETL) and/or an electron injection layer (EIL). Similar to an opposite electrode 213 to be described below, the first functional layer 212a and/or the second functional layer 212c may be a common layer entirely covering the substrate 100.

The opposite electrode 213 may include a conductive material having a low work function. For example, the opposite electrode 213 may include a (semi)transparent layer, the (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or alloys thereof. Alternatively, the opposite electrode 213 may further include a layer, such as ITO, IZO, ZnO, or In₂O₃, above the (semi)transparent layer including one or more of the conductive materials stated above.

In some embodiments, a capping layer may be further disposed on the opposite electrode 213. The capping layer may include lithium fluoride (LiF), an inorganic material, and/or an organic material.

The thin-film encapsulation layer TFE may be disposed on the opposite electrode 213. In an embodiment, the thin-film encapsulation layer TFE may include at least one inorganic encapsulation layer and at least one organic encapsulation layer. For example, the thin-film encapsulation layer TFE may include a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acrylic resin, an epoxy resin, polyimide, polyethylene, or a combination of two or more of these materials. In an embodiment, the organic encapsulation layer 320 may include acrylate.

As illustrated in FIG. 6, the layer structure of the display panel 10 may include a sequential stacking configuration. The inorganic insulating layer IIL may include, in order from bottom to top, the buffer layer 111, the first gate insulating layer 112, the second gate insulating layer 113, and the interlayer insulating layer 114. The pixel circuit layer PCL may be disposed on the inorganic insulating layer IIL, and may include, in sequential order, the first planarization layer 115 and the second planarization layer 116. The pixel electrode 211 may be disposed on the second planarization layer 116. The display element layer DEL may be disposed on the pixel electrode 211 and may cover at least a portion of an upper surface of the pixel electrode 211. The display element layer DEL may include, in sequential order, the pixel defining layer 118, the intermediate layer 212, and the opposite electrode 213. The thin-film encapsulation layer TFE may be disposed on the display element layer DEL and may include, in sequential stacking, the first inorganic encapsulation layer 310, the organic encapsulation layer 320, and the second inorganic encapsulation layer 330.

In some aspects, the first planarization layer 115 and the second planarization layer 116 may provide a planar surface for uniform deposition of the pixel electrode 211 and subsequent organic layers of the display element layer DEL. In some aspects, the thin-film encapsulation layer TFE may serve as a barrier to moisture and oxygen, thereby enhancing the operational stability and lifespan of the display element DE.

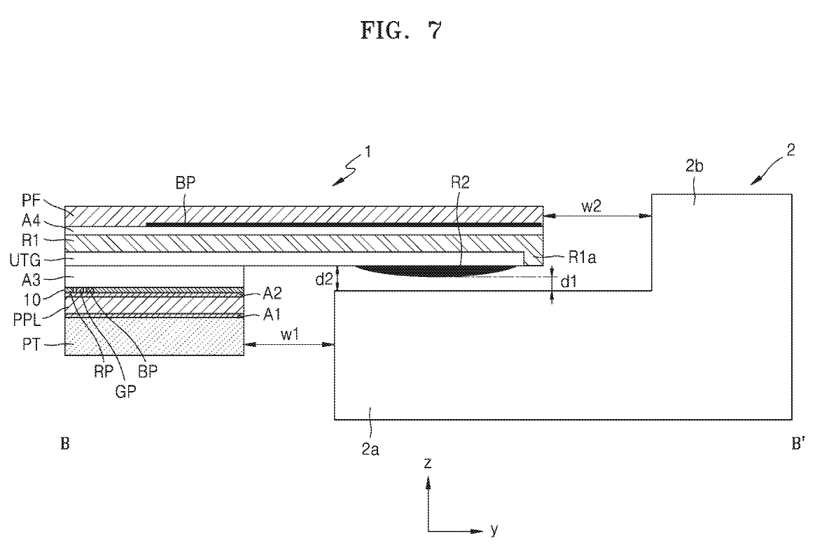

FIG. 7 is a cross-sectional view schematically illustrating an example of the cross-section of the display device taken along a line B-B' of FIG. 1, and FIG. 8 is a cross-sectional view schematically illustrating an example of the cross-section of the display device taken along a line E-E' of FIG. 1.

Referring to FIGS. 7 and 8 together with FIG. 1, the electronic device 1000 may include a lower member, the display panel 10, and a window, which are sequentially stacked in a first direction z. For example, the lower member refers to a configuration disposed on the lower side of the display panel 10.

As described above with reference to FIG. 6, the display panel 10 may include the substrate 100, the buffer layer 111, the pixel circuit layer PCL, the display element layer DEL, and the thin-film encapsulation layer TFE. In some embodiments, the display panel 10 may include a red pixel RP that emits red light, a green pixel GP that emits green light, and a blue pixel BP that emits blue light. However, as shown in FIG. 7, the red pixel RP, the green pixel GP, and the blue pixel BP are not necessarily disposed in an order, and the red pixel RP, the green pixel GP, and the blue pixel BP may be disposed in various orders.

The window may include a glass layer UTG, a first cover layer R1 disposed on the glass layer UTG, a window protection layer PF disposed on the first cover layer R1, and a bezel pattern BP disposed on a lower surface of the window protection layer PF. The window structure may

protect the display panel 10 from mechanical and environmental stress while maintaining transparency and touch sensing. In an embodiment, the fourth adhesive layer A4 may be disposed between the first cover layer R1 and the window protection layer PF. Further detail on the adhesive layer is described below.

In an embodiment, the window protection layer PF may absorb external impact applied to the front surface of the display panel 10. The window protection layer PF may include, for example, a synthetic resin film. The synthetic resin film of the window protection layer PF may include at least one of polyimide, polycarbonate (PC), polyamide, triacetylcellulose, polymethylmethacrylate, or polyethylene terephthalate (PET). In some embodiments, the thickness of the window protection layer PF measured in the z direction may be, for example, about 50 μm to about 80 μm.

In an embodiment, a functional layer may be further disposed on the window protection layer PF. The functional layer may include at least one of a hard coating layer, an anti-fingerprint layer, or an anti-reflection layer. These functional layers may enhance surface hardness of the display device.

The bezel pattern BP may be disposed on one surface of the glass layer UTG, one surface of the first cover layer R1, or one surface of the window protection layer PF. FIGS. 7 and 8 illustrate the bezel pattern BP disposed on the lower surface of the window protection layer PF, but the disclosure is not necessarily limited thereto. For example, the bezel pattern BP may be disposed on the upper surface of the window protection layer PF. The bezel pattern BP may include, for example, a colored light-blocking film. The bezel pattern BP may shield peripheral circuitry from view and reduce optical leakage from edge pixels.

The bezel pattern BP may be formed, for example, by a coating method. The bezel pattern BP may include a base material and a dye or pigment mixed into the base material. The peripheral area PA illustrated in FIG. 2 may be defined by the shape of the bezel pattern BP.

The window protection layer PF and the first cover layer R1 may be coupled to each other by a fourth adhesive layer A4. The fourth adhesive layer A4 may include a pressure sensitive adhesive (PSA) film or an optically clear adhesive (OCA). Adhesive layers A1, A2, A3, and A5 to be described below may also include an adhesive of the same type as the adhesive of the fourth adhesive layer A4.

The first cover layer R1 may include a natural resin film or a synthetic resin film. The synthetic resin film may include at least one of polyimide, polycarbonate (PC), polyamide, triacetylcellulose, polymethylmethacrylate, or polyethylene terephthalate (PET). The first cover layer R1 may absorb external impact applied to the front surface of the display panel 10 together with the window protection layer PF.

The glass layer UTG may be disposed below the first cover layer R1. The glass layer UTG may include chemically strengthened glass. For example, the glass layer UTG may include ultra-thin glass or hybrid thin glass. The glass layer UTG may provide mechanical strength and flexibility to the display device 1, thereby reducing the occurrence of wrinkles in the display device 1 even when the display device 1 is repeatedly folded and unfolded. In some embodiments, a bottom surface of the glass layer UTG may be at a level substantially the same as a bottom surface of the first cover layer R1.

At this time, the thickness of the glass layer UTG may be, for example, about 15 μm to about 45 μm. In some embodiments, the glass layer UTG may be coupled to the display panel 10 via a third adhesive layer A3. The lower member may be disposed below the display panel 10. The third adhesive layer A3 may be configured to maintain optical transparency and flexibility while bonding the UTG to the display panel 10 without delamination during folding.

The lower member may include a panel protection film PPL, a lower plate PT, and a cushion layer CS. The panel protection film PPL may be disposed on the lower side of the display panel 10 to be coupled with the display panel 10 via a second adhesive layer A2. Accordingly, the panel protection film PPL may protect the lower portion of the display panel 10. The panel protection film PPL may include, for example, a flexible synthetic resin film. The panel protection film PPL may also serve to buffer mechanical stress transferred from the lower plate PT.

In some embodiments, the panel protection film PPL may include a base film and a shielding part. The base film may include at least one of polyurethane and polyimide. The shielding part may include magnetic metal powder (MMP). Accordingly, the panel protection film PPL according to the disclosure may have an electromagnetic shielding function. The shielding part may be disposed on the upper surface of the panel protection film PPL, which is adjacent to the display panel 10, or the magnetic metal powder MMP may be disposed inside the panel protection film PPL.

The panel protection film PPL might not be disposed in the bending area BA. For example, the panel protection film PPL might not be disposed in the bending area BA, but may be disposed in the display area DA and the pad area PDA.

As shown in FIG. 3, the bending area BA may be bent based on a virtual bending axis BAX extending in the third direction x. In some cases, when the bending area BA is bent, the panel protection film PPL disposed in the pad area PDA may be disposed on the lower side of the panel protection film PPL disposed in the display area DA and may be attached to the cushion layer CS. Accordingly, because the panel protection film PPL is not disposed in the bending area BA, the bending area BA may be bent more easily compare to a case where the panel protection film PPL is disposed in the bending area BA. The absence of panel protection film PPL in the bending area BA may reduce mechanical resistance during folding and prevent delamination or stress concentration at the fold.

The bending area BA has a curvature and radius of curvature in the bent state. For example, the radius of curvature of the bending area BA may be about 0.1 mm to 0.5 mm.

A bending protection layer BPL may be disposed in a portion of the bending area BA, a portion of the display area DA, and a portion of the pad area PDA. For example, the bending protection layer BPL may be disposed over the entire area of the bending area BA, a portion of the display area DA, and a portion of the pad area PDA. The bending protection layer BPL may be configured to distribute mechanical strain during repeated folding operations and protect the electronic components from fracture or fatigue.

The bending protection layer BPL may be bent together with the bending area BA. The bending protection layer BPL may protect the bending area BA from external impact and control the neutral plane of the bending area BA.

When the bending area BA is bent, the integrated circuit 30 and the flexible circuit board 40, which are disposed in the pad area PDA, may overlap the rear surface of the display panel 10 that overlaps the display area DA.

The circuit cover C-IC may be attached to the integrated circuit 30 and the flexible circuit board 40 in the pad area PDA. For example, the circuit cover C-IC may be disposed at an end of the bending protection layer BPL to cover the integrated circuit 30 and the flexible circuit board 40.

The lower plate PT may be disposed below the panel protection film PPL. The lower plate PT and the panel protection film PPL may be coupled to each other via a first adhesive layer A1.

In an embodiment, a barrier layer may be disposed between the lower plate PT and the panel protection film PPL. The barrier layer may increase resistance to compressive force due to external pressure. Therefore, the barrier layer may serve to prevent transformation of the display panel 10.

The barrier layer may include a flexible plastic material, such as polyimide, polycarbonate (PC), polyamide, triacetylcellulose, polymethylmethacrylate, or polyethylene terephthalate (PET).

In some embodiments, the barrier layer may include a colored film having low light transmittance. For example, the barrier layer may absorb light incident from the outside. For example, the barrier layer may include a black synthetic resin film. As a result, when viewing the display panel 10 from the upper side of the window protection layer PF, components disposed below the barrier layer might not be visible to the user. In some cases, the barrier layer may visually conceal components located beneath the barrier layer when the display panel 10 is viewed through the window protection layer PF.

The lower plate PT may support the display panel 10. The lower plate PT may include, for example, a material having an elastic modulus of 60 GPa or more at room temperature. The lower plate PT may enhance the heat radiation performance of the electronic device 1000 including the display device 1 by including a single metal material or an alloy of a plurality of metal materials. For example, the lower plate PT may include stainless steel, but is not necessarily limited thereto, and the lower plate PT may include various metal materials. In some cases, the lower plate PT may include a single metal material or an alloy comprising two or more metals. In an embodiment, a heat radiation layer may be disposed below the lower plate PT.

The cushion layer CS may be disposed below the lower plate PT. However, the disclosure is not necessarily limited thereto, and the positions of the lower plate PT and the cushion layer CS may be interchanged. The cushion layer CS may contact a rear housing or support structure of the electronic device 1000.

The cushion layer CS may prevent the display panel 10 from being damaged. The cushion layer CS may protect the display panel 10 from impact transmitted from the lower portion of the display panel 10. For example, the cushion layer CS may include foam or sponge. The foam may include a polyurethane foam or a thermoplastic polyurethane foam. When the cushion layer CS includes a foam, a barrier film may be added as a base layer to the cushion layer CS, and a foaming agent may be foamed onto the barrier film to form the cushion layer CS. The barrier film may be disposed on a bottom surface of the cushion layer CS.

The electronic device 1000 (refer to FIG. 1) may include an extension part 2b positioned along the outer periphery of the display device 1 and extending in the first direction z, and a protrusion part 2a protruding from the extension part 2b in the second direction y crossing (or perpendicular to) the first direction z, and may include the frame 2 that accommodates the display device 1. The extension part 2b may define a sidewall of the frame 2, and the protrusion part 2a may define a support surface extending inward toward the display device 1.

For example, the frame 2 may have a stepwise step-difference on the outer periphery of the display device 1. In FIGS. 7 and 8, the frame 2 is illustrated as having a stepwise step-difference along the second direction y, but is not necessarily limited thereto, and the frame 2 may also have a stepwise step-difference along the third direction x. In some cases, the cross section of the frame 2 may have a polygon shape.

The window including the glass layer UTG, the first cover layer R1 disposed on the glass layer UTG, and the window protection layer PF disposed on the first cover layer R1 may be further extended toward the extension part 2b along the second direction y. The extension length of the window (e.g., window protection layer PF) may be about 0.8 mm to about 1.5 mm. For example, the window may further extend about 0.8 mm to about 1.5 mm toward the extension part 2b along the second direction y than the display panel 10. In some cases, the first cover layer R1 and the window protection layer PF may laterally extend beyond the edge of the glass layer UTG in the second direction y. For example, an extension of approximately 0.1 mm to 0.3 mm may be provided to allow for secure bonding between layers via the fourth adhesive layer A4. This configuration may also contribute to impact mitigation and enhance optical concealment of internal components.

The window may be spaced apart from the extension part 2b in the second direction y, and the lower plate PT may be spaced apart from the protrusion part 2a in the second direction y. Because the window may include various layers as described above, the window protection layer PF is described as an example instead of the window.

A ratio of a separation distance w2 between the extension part 2b and the window protection layer PF in the second direction y to a separation distance w1 between the protrusion part 2a and the lower plate PT in the second direction y may be about 0.8 to about 1.2. In an embodiment, the separation distance w2 between the extension part 2b and the window protection layer PF in the second direction y and the separation distance w1 between the protrusion part 2a and the lower plate PT in the second direction y may be the same. In some cases, the first separation distance w1 and second separation distance w2 may be equal.

When the ratio of the second separation distance w2 between the extension part 2b and the window protection layer PF in the second direction y to the first separation distance w1 between the protrusion part 2a and the lower plate PT in the second direction y is about is 0.8 to about 1.2, and When an impact is applied to the electronic device 1000 in a direction parallel to the second direction y, when the impact is applied to the protrusion part 2a of the frame 2 and the lower plate PT, the impact may also be applied to the extension part 2b of the frame and the window protection layer PF. As a result, the impact is dispersed, and the stability of the electronic device 1000 including the display device 1 may be improved. In some cases, the spatial relationship between the first separation distance w1 and the second separation distance w2 may allow the extension part 2b and the protrusion part 2a to be aligned with the window protection layer PF and the lower plate PT, respectively, along the second direction y.

In an embodiment, the lower plate PT may be extended further toward the protrusion part 2a than the display panel 10, so when an impact is applied to the electronic device 1000 in a direction parallel to the second direction y, the lower plate PT may first collide with the protrusion part 2a before the display panel 10, thereby reducing the impact applied to the display panel 10. For example, a side edge of the lower plate PT may be positioned closer to the protrusion part 2a than a side edge of the display panel 10.

Similarly, to protect the glass layer UTG which is highly brittle, the first cover layer R1 may include a first folded part R1a that is folded toward the glass layer UTG. As a result, When an impact is applied to the electronic device 1000 in a direction parallel to the second direction y, the first folded part R1a may first collide with the extension part 2b before the glass layer UTG, thereby reducing the impact applied to the glass layer UTG. The first folded part R1a may extend in the second direction y to a position closer to the extension part 2b than the glass layer UTG.

As described above, the frame 2 may have a stepwise step-difference in the third direction x, so that the ratio of the distance between the extension part 2b and the window protection layer PF in the third direction x to the distance between the protrusion part 2a and the lower plate PT in the third direction x may also be about is 0.8 to about 1.2. For example, when an impact is applied to the electronic device 1000 in a direction parallel to the third direction x, the impact is applied together to the lower plate PT and the window protection layer PF, thereby dispersing the impact to improve the stability of the electronic device 1000.

Conventional electronic device may include a window protection layer PF that does not extend further than the display panel 10 toward the frame 2 having a stepwise step-difference, and the display panel 10 is spaced apart from the frame 2. For example, foreign materials, such as moisture, may enter from the outside of the electronic device 1000 through the separation space between the display panel 10 and the frame 2. Accordingly, some conventional electronic devices may include a separate cover used to protect the display panel 10 to cover the separation space described above. As a result, the separate cover is visible at the boundary between the display device 1 and the frame 2, which reduces the aesthetics of the electronic device 1000. For example, to reduce exposure of the separation space between the display panel 10 and the frame 2, conventional electronic devices include a cover structure positioned at the boundary between the display panel 10 and the frame 2. The cover was visibly distinguishable from the surrounding layers.

However, in embodiments of the disclosure, a separate cover covering the separation space described above may be omitted, and the window protection layer PF extending toward the extension part 2b of the frame 2 may protect the display panel 10 from foreign materials that may enter from the outside of the electronic device 1000, thereby improving the aesthetics of the electronic device 1000. The window protection layer PF may be extended to overlap the extension part 2b of the frame 2 so that the separation space is concealed without requiring an additional cover.

The second separation distance w2 between the extension part 2b and the window protection layer PF in the second direction y may be about 0.3 mm to about 0.7 mm. When the separation distance w2 between the extension part 2b and the window protection layer PF in the second direction y is less than 0.3 mm, and an impact is applied to the electronic device 1000 in a direction parallel to the second direction y, a slight impact may cause the extension part 2b and the window protection layer PF to collide, thereby reducing the durability of the window protection layer PF. When the second separation distance w2 is less than 0.3 mm, the extension part 2b and the window protection layer PF may be positioned sufficiently close to make direct contact during minor deformation or vibration. In some embodiments, when the second separation distance w2 between the extension part 2b and the window protection layer PF in the second direction y exceeds 0.7 mm, foreign materials may penetrate into the separation space between the extension part 2b and the window protection layer PF. When the second separation distance w2 exceeds 0.7 mm, the open gap between the extension part 2b and the window protection layer PF may be enlarged to a degree that allows ingress of particulates or moisture.

In an embodiment, the extension part 2b of the frame 2 may further include a second protrusion part that protrudes in the same direction as the protrusion part 2a to cover the separation space between the extension part 2b and the window protection layer PF. In this way, When the frame 2 further includes a second protrusion part, the second protrusion part may protect the display panel 10 from foreign materials that may enter from the outside of the electronic device 1000 via the separation space by covering the separation space between the extension part 2b and the window protection layer PF.

A first distance d2 between the bottom surface (or the lowermost section) of the glass layer UTG and the protrusion part 2a in the first direction z may be about 0.025 mm to about 0.1 mm. When the first distance d2 between the bottom surface of the glass layer UTG and the protrusion part 2a in the first direction z is less than 0.025 mm, when an impact is applied to the electronic device 1000 in a direction parallel to the first direction z, mechanical stress may cause the glass layer UTG and the protrusion part 2a to collide with each other, causing the glass layer UTG to be damaged. In some embodiments, when the first distance d2 between the bottom surface of the glass layer UTG and the protrusion part 2a in the first direction z exceeds 0.1 mm, foreign materials may penetrate into the separation space between the glass layer UTG and the protrusion part 2a as described above. For example, the first distance d2 may be set within the range of 0.025 mm to 1.0 mm to ensure both impact mitigation and adequate sealing without introducing excessive material gaps.

The electronic device 1000 may further include a second cover layer R2 covering at least a portion of the bottom surface of the glass layer UTG. In some cases, the electronic device 1000 further includes the second cover layer R2 covering at least a portion of the bottom surface of the glass layer UTG, when an impact is applied to the electronic device 1000 in a direction parallel to the first direction z, the second cover layer R2 may absorb the impact, thereby preventing the glass layer UTG from colliding with the protrusion part 2a to cause damage of the glass layer UTG. The second cover layer R2 may be interposed between the glass layer UTG and adjacent structures along the first direction z. In some cases, the second cover layer R2 may extend over the entire lower surface of the glass layer UTG or be locally applied in the area adjacent to the protrusion part 2a.

In some embodiments, the second cover layer R2 may include a material that serves as a light shield. For example, the second cover layer R2 includes a material that serves as a light shield, light leakage from the display panel 10 may be prevented, thereby increasing the clarity and contrast of the display device 1 and reducing the sub-pixels of the display panel 10 from being interfered by ambient light coming from the outside the electronic device 1000 or reflected light from internal components of the electronic device 1000. For example, the light-shielding layer may prevent entry of ambient light from the outer environment or reflection from internal elements such as metallic traces or substrates.

Accordingly, the second cover layer R2 may include at least one of a black resin, a carbon black resin, an organic light absorber, a silica composite resin, or a black polyimide resin.

The second cover layer R2 may be spaced apart from the protrusion part 2a in the first direction z. For example, a ratio of a thickness d2 and d1 of the second cover layer R2 to the separation distance d2 between the bottom surface of the glass layer UTG and the protrusion part 2a may be about 0.25 to about 0.8. In some cases, the separation distance d1 may be referred to as the second distance.

In an embodiment, when folding the foldable display device 1, a slip may occur between bonding layers between components of the display device 1 or between the display device 1 and the frame 2. When a slip occurs, uniform folding of the electronic device 1000 may be ensured, and when the electronic device 1000 is repeatedly folded, repetitive fatigue between the bonding layers between the components of the display device 1 or between the display device 1 and the frame 2 may be reduced. However, when the slip is excessive or uneven, wrinkles may form between layers, or stress may be applied between layers, causing separation between layers.

When the ratio of the thickness d2 and d1 of the second cover layer R2 to the separation distance d2 between the bottom surface of the glass layer UTG and the protrusion part 2a in the first direction z is less than 0.25, the thickness of the second cover layer R2 may be too thin, and the protection of the glass layer UTG by the second cover layer R2 may be insufficient. For example, the second cover layer R2 may lack sufficient thickness to provide adequate buffering, potentially reducing the impact protection offered to the glass layer UTG. In some embodiments, when the ratio of the thickness d2 and d1 of the second cover layer R2 to the separation distance d2 between the bottom surface of the glass layer UTG and the protrusion part 2a in the first direction z exceeds 0.8, a slip may occur in the display device 1, and the second cover layer R2 and the protrusion part 2a may come into contact, causing stress due to slip.

Referring to FIG. 8, the window may be spaced apart from the extension part 2b in the second direction y, and the bending protection layer BPL may be spaced apart from the protrusion part 2a in the second direction y. Because the window may include various layers as described above, in the following description, the window protection layer PF is described as an example instead of the window.

In some embodiments, a ratio of a separation distance w4 between the extension part 2b and the window protection layer PF in the second direction y to a separation distance w3 between the protrusion part 2a and the bending protection layer BPL in the second direction y may be about 0.8 to about 1.2. In an embodiment, the separation distance w4 between the extension part 2b and the window protection layer PF in the second direction y and the separation distance w3 between the protrusion part 2a and the bending protection layer BPL in the second direction y may be the same. Here, the ‘separation distance between the protrusion part 2a and the bending protection layer BPL’ represents the closest distance between the protrusion part 2a and the bending protection layer BPL in the second direction y. For example, the separation distance w4 may correspond to the shortest lateral distance between a side surface of the extension part 2b and a side surface of the window protection layer PF in the second direction y, and similarly, the separation distance w3 may correspond to the shortest lateral distance between a side surface of the protrusion part 2a and a side surface of the bending protection layer BPL.

When the ratio of the separation distance w4 between the extension part 2b and the window protection layer PF in the second direction y to the separation distance w3 between the protrusion part 2a and the bending protection layer BPL in the second direction y is about 0.8 to about 1.2, as described above, when an impact is applied to the electronic device 1000 in a direction parallel to the second direction y, the impact may be distributed across both the upper and lower structural regions, thereby enhancing the stability of the electronic device 1000 including the display device 1.

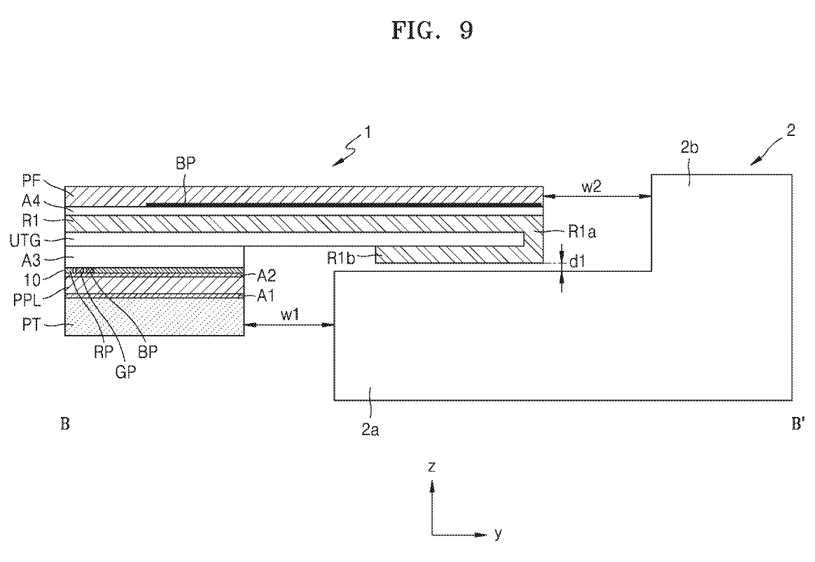

FIG. 9 is a cross-sectional view schematically illustrating an example of the cross-section of the display device taken along a line B-B' of FIG. 1.

The embodiment described in FIG. 9 may be identical to the embodiment described in FIGS. 7 and 8 except for a second folded part R1b, and therefore, the differences are described below.

Referring to FIG. 9, the electronic device 1000 (refer to FIG. 1) may include the display device 1 including the lower plate PT, the display panel 10, the glass layer UTG, the first cover layer R1, and the window protection layer PF, which are sequentially stacked in the first direction z, the extension part 2b positioned along the outer periphery of the display device 1 and extending in the first direction z, and the protrusion part 2a protruding from the extension part 2b in the second direction y perpendicular to the first direction z, and may include the frame 2 accommodating the display device 1. The first cover layer R1 may be contoured to cover the upper surface and the edge and lower surface of the glass layer UTG via folding sections.

The first cover layer R1 may include the first folded part R1a that is folded toward the glass layer UTG, and the second folded part R1b that is folded from the first folded part R1a toward the bottom surface of the glass layer UTG to cover the bottom surface of the glass layer UTG. In some embodiments, the second folded part R1b may be spaced apart from the protrusion part 2a in the first direction z. For example, a ratio of a thickness d2 and d1 of the second folded part R1b to the separation distance d2 (refer to FIG. 7) between the bottom surface of the glass layer UTG and the protrusion part 2a may be about 0.25 to about 0.8. The second folded part R1b may form a protective cover below the glass layer UTG without direct contact with the frame 2.

When the ratio of the thickness d2 and d1 of the second folded part R1b to the separation distance d2 between the bottom surface of the glass layer UTG and the protrusion part 2a in the first direction z is less than 0.25, the thickness of the second folded part R1b may be too thin, and the protection of the glass layer UTG by the second folded part R1b may be insufficient. For example, the second folded part R1b might not provide sufficient coverage to physically isolate the glass layer UTG from the protrusion part 2a. In some embodiments, When the ratio of the thickness d2 and d1 of the second folded part R1b to the separation distance d2 between the bottom surface of the glass layer UTG and the protrusion part 2a in the first direction z exceeds 0.8, the second folded part R1b and the protrusion part 2a may come into contact, causing stress due to slip and resulting in unintended mechanical interference or stress accumulation.

When the first cover layer R1 includes the first folded part R1a and the second folded part R1b to surround at least a portion of the glass layer UTG, the first folded part R1a and the second folded part R1b may use the same material, thereby preventing interface stress that may occur when bonding different materials. In some embodiments, manufacturing processes of the display device 1 and the electronic device 1000 including the display device 1 may be simplified, so that the efficiency of the process of the display device 1 and the electronic device 1000 including the display device 1 may be improved. In some cases, forming the folded parts from a single continuous layer may reduce the number of manufacturing steps, which may simplify assembly and improve process uniformity.

In some embodiments, the second folded part R1b may have a curved or rounded profile at the fold transition region from the first folded part R1a. This curvature may reduce localized mechanical stress concentration that could otherwise occur at sharp bends. In some cases, the bending radius may be based on the material properties of the first cover layer R1. In an embodiment, the second folded part R1b may be configured to overlap at least a portion of the lower edge of the glass layer UTG and may optionally be bonded to the UTG or an adjacent adhesive layer (e.g., A3). This bonded configuration may enhance alignment stability of the UTG within the multilayer structure. In some cases, second folded part R1b may remain non-bonded and function as a protective portion.

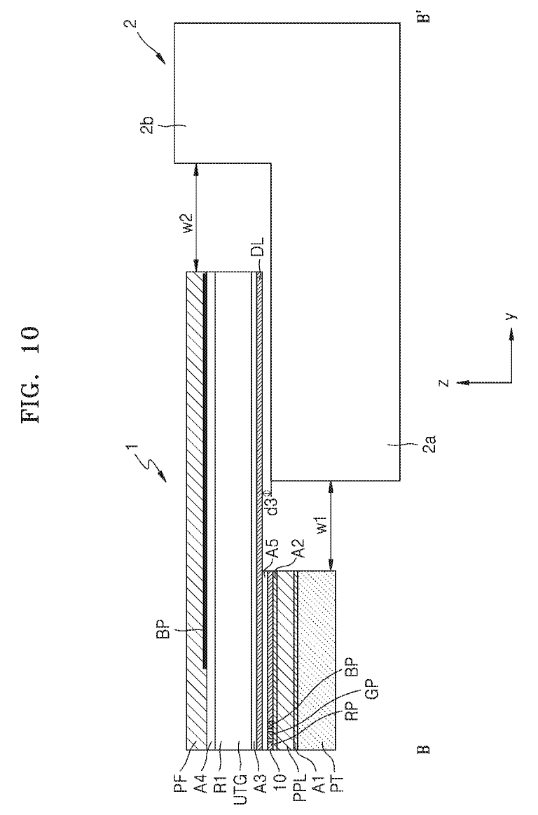

FIG. 10 is a cross-sectional view schematically illustrating an example of the cross-section of the display device taken along a line B-B' of FIG. 1.

In the description with reference to FIG. 10, the differences from the previously described embodiments are described. Accordingly, components and layer sequences that are common to those in FIGS. 7-9 might not be described.

Referring to FIG. 10, the electronic device 1000 (refer to FIG. 1) may include the display device 1 including the lower plate PT, the display panel 10, an upper protection film DL, the glass layer UTG, the first cover layer R1, and the window protection layer PF, which are sequentially stacked in the first direction z, the extension part 2b positioned along the outer periphery of the display device 1 and extending in the first direction z, and the protrusion part 2a protruding from the extension part 2b in the second direction y perpendicular to the first direction z, and may include the frame 2 accommodating the display device 1. In some cases, for example, upper protection film DL may be disposed between the display panel 10 and the glass layer UTG and may function as an additional protective layer.

The upper protection film DL may cover the upper surface of the display panel 10 and protect the display panel 10 from impact applied from the upper portion of the display panel 10. The upper protection film DL and the display panel 10 may be coupled to each other via a fifth adhesive layer A5. The fifth adhesive layer A5 may include the same material as the first to fourth adhesive layers A1, A2, A3, and A4.

The upper protection film DL may include a synthetic resin film. The synthetic resin film may include at least one of polyimide, PC, polyamide, triacetylcellulose, polymethylmethacrylate, or polyethylene terephthalate (PET).

The window may include the upper protection film DL, the glass layer UTG, the first cover layer R1 disposed on the glass layer UTG, the window protection layer PF disposed on the first cover layer R1, and the bezel pattern BP disposed on the lower surface of the window protection layer PF. In some cases, the upper protection film DL, the glass layer UTG, the first cover layer R1 may be vertically stacked in the first direction z.

In some embodiments, the window may be further extended toward the extension part 2b to be spaced apart from the protrusion part 2a in the first direction z, and the window may be spaced apart from the extension part 2b in the second direction y. At this time, the upper protection film DL may be spaced apart from the extension part 2b by a constant distance d3 in the first direction z. The distance d3 may represent a clearance gap between the lower surface of the DL and the upper surface of the protrusion part 2a.

When the upper protection film DL is spaced apart from the extension part 2b by the constant distance d3 in the first direction z, when an impact is applied to the electronic device 1000 in a direction parallel to the first direction z, the impact applied to the glass layer UTG through the upper protection film DL may be reduced because the upper protection film DL is spaced apart from the extension part 2b. In some embodiments, when a slip occurs in the display device 1, stress caused by the slip due to contact between the upper protection film DL and the protrusion part 2a may be reduced.

The upper protection film DL may be disposed below the glass layer UTG to protect the glass layer UTG, and the first cover layer R1 may be disposed on the glass layer UTG to protect the glass layer UTG, thereby increasing the thickness of the glass layer UTG. Accordingly, the mechanical strength, durability, and lifespan of the glass layer UTG may be improved.

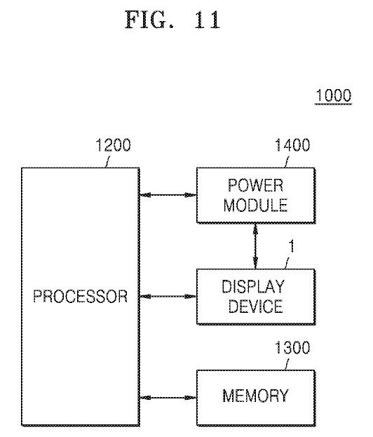

FIG. 11 is a block diagram of an electronic device according to an embodiment.

Referring to FIG. 11, the electronic device 1000 according to an embodiment may include the display device 1, a processor 1200, a memory 1300, and a power module 1400.

The display device 1 may receive data from the processor 1200 to provide visual information. The display device 1 may be the display device 1 according to the embodiments of the disclosure described above.

The processor 1200 may include at least one of a central processing unit CPU, an application processor AP, a graphics processing unit GPU, a communication processor CP, an image signal processor ISP, and a controller. For example, the processor 1200 may may execute instructions stored in the memory 1300 to perform control operations associated with signal processing and display control.

Data information necessary for the operation of the processor 1200 or display device 1 may be stored in the memory 1300. For example, the memory 1300 may store at least one program described above. When the processor 1200 executes an application stored in the memory 1300, an image data signal and/or an input control signal may be transmitted to the display device 1, and the display device 1 may process the received signal and output image information through a display screen.

The power module 1400 may include a power supply module, such as a power adapter or a battery device, and a power conversion module that converts power supplied by the power supply module to generate power required for the operation of the electronic device 1000. For example, the power module 1400 may supply electricity to the display device 1.

At least one of the components of the above-described electronic device 1000 may be included in the display device 1 according to the above-described embodiments. In some embodiments, some of the individual modules functionally included in one module may be included in the display device 1, and other individual modules may be provided separately from the display device 1.

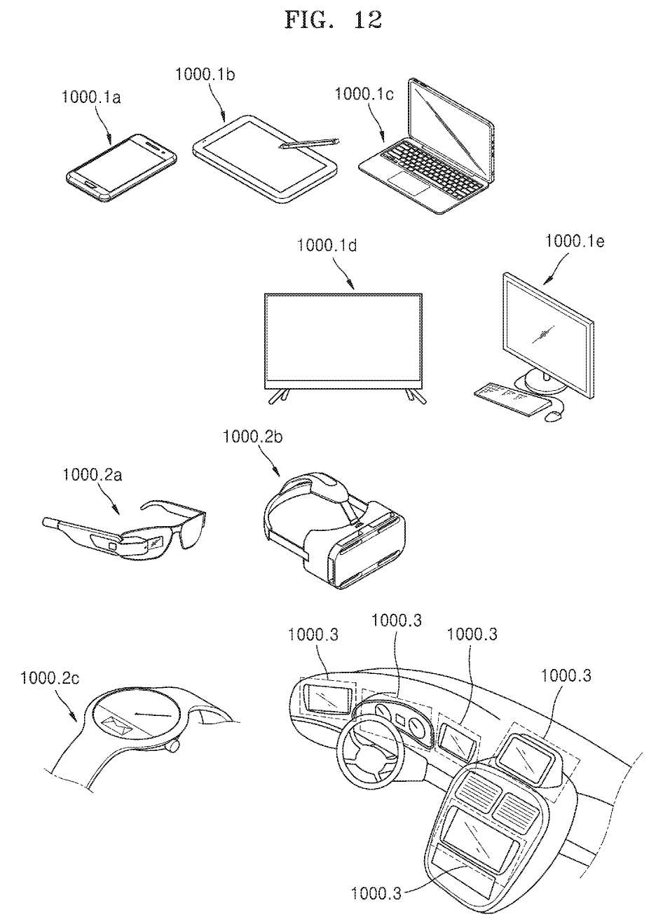

FIG. 12 is a schematic diagram of an electronic device according to various embodiments.

Referring to FIG. 12, various electronic devices to which a display device according to embodiments of the disclosure is applied may include image display electronic devices, such as a smart phone 1000.1a, a tablet PC 1000.1b, a laptop 1000.1c, a television (TV) 1000.1d, a desktop monitor 1000.1e, and wearable electronic devices including display devices such as smart glasses 1000.2a, a head-mounted display (HMD) 1000.2b, a smart watch 1000.2c. In addition, the display device may include vehicle electronic devices 1000.3 such as a dashboard of a vehicle, a center fascia, a CID disposed on the dashboard, and a room mirror display.

According to embodiments of the disclosure, the aesthetics of a display device and an electronic device including the display device can be improved without using a separate cover, which protects a display panel, between the display device and the frame.

In some embodiments, as the frame having a stepwise frame structure and a lower plate that supports a window layer are spaced apart from display panel based on a predetermined ratio, mechanical impact applied to the electronic device including the display device may be effectively dispersed. Accordingly, the stability of the display device and the electronic device including the display device may be enhanced.

However, effects achieved through the present disclosure are not necessarily limited to those explicitly described above. Additional technical effects not mentioned can be clearly understood by those skilled in the art from the description of the disclosure described above.

Each of the embodiments described above may be implemented independently, and the structure of each embodiment may be applied in combination to other embodiments.

Although the disclosure has been described with reference to the embodiments shown in the drawings, these are merely examples, and those skilled in the art will understand that various modifications and equivalent other embodiments are possible therefrom. Therefore, the true technical protection scope of the disclosure should be determined by the technical idea of the appended patent claims.

The specific implementations described in the embodiments are merely examples and do not necessarily limit the scope of the embodiments in any way. Also, if there is no specific mention such as “essential” or “important,” a component might not be an essential component for the application of the disclosure.

The use of the term “a”, “an”, “the", and similar referential terms in the specification of embodiments (especially in the claims) may refer to both the singular and the plural.

In addition, when a range is described in an embodiment, it is considered that the disclosure includes an individual value that falls within the range (unless otherwise stated), and it is the same as describing each individual value that constitutes the range in the detailed description.

Finally, unless expressly stated otherwise, or unless the context clearly dictates a specific order, the operations constituting the method according to an embodiment may be performed in any suitable sequence. The embodiments are not necessarily limited to the particular order in which the operations are described above.

Any use of examples or terms in the embodiments is merely intended to elaborate the embodiments and is not intended to limit the scope of the embodiments, unless otherwise defined by the claims.

Furthermore, those skilled in the art will appreciate that various modifications, combinations and variations may be made according to design conditions and factors within the scope of the appended claims or their equivalents.

What is claimed is:

1. An electronic device, comprising:
a display device comprising:
a lower plate,
a display panel disposed on the lower plate,
a glass layer disposed on the display panel, and
a window protection layer disposed on the glass layer, wherein the lower plate, the display panel, the glass layer, and the window protection layer are sequentially stacked in a first direction; and
a frame accommodating the display device, wherein the frame comprises:
an extension part disposed along an outer periphery of the display device and extending in the first direction, and
a protrusion part protruding from the extension part in a second direction crossing the first direction,
wherein a first separation distance is measured between the protrusion part and the lower plate in the second direction,
wherein a second separation distance is measured between the extension part and the window protection layer in the second direction, and
wherein a ratio of the second separation distance to the first separation distance is about 0.8 to about 1.2.

2. The electronic device of claim 1, further comprising:
a first cover layer disposed between the glass layer and the window protection layer and extending in the second direction,
wherein the first cover layer includes a first folded part folded toward the glass layer.

3. The electronic device of claim 2, wherein the first cover layer further comprises:
a second folded part extending from the first folded part toward a bottom surface of the glass layer and covers at least a portion of the bottom surface of the glass layer.

4. The electronic device of claim 2, further comprising:
a second cover layer disposed on and covering at least a portion of a bottom surface of the glass layer.

5. The electronic device of claim 4, wherein the second cover layer comprises:
at least one of a black resin, a carbon black resin, an organic light absorber, a silica composite resin, or a black polyimide resin.

6. The electronic device of claim 4, wherein:
the second cover layer is spaced apart from the protrusion part of the frame in the first direction.

7. The electronic device of claim 6, wherein:
a first distance between the bottom surface of the glass layer and the protrusion part of the frame is about 0.025 mm to about 0.1 mm.

8. The electronic device of claim 7, wherein:
a second distance is measured between the second cover layer and an upper surface of the protrusion part of the frame, and
wherein a ratio of the first distance and the second distance is about 0.25 to about 0.8.

9. The electronic device of claim 1, wherein:
the second separation distance is about 0.3 mm to about 0.7 mm.

10. The electronic device of claim 1, wherein the first separation distance is equal to the second separation distance.

11. An electronic device, comprising:
a display device including:
a display panel,
a glass layer disposed on the display panel,
a first cover layer disposed on the glass layer, and
a window protection layer disposed on the first cover layer, wherein the display panel, the glass layer, the first cover layer, and the window protection layer are sequentially stacked in a first direction and extend in a second direction crossing the first direction; and
a frame accommodating the display device, wherein the frame includes:
an extension part disposed along an outer periphery of the display device and extending in the first direction, and
a protrusion part protruding from the extension part in the second direction,
wherein the glass layer and the window protection layer further extend toward the extension part and are spaced apart from the protrusion part in the first direction, and
wherein the window protection layer is spaced apart from the extension part in the second direction.

12. The electronic device of claim 11, wherein:
an extension length of the window protection layer is about 0.8 mm to about 1.5 mm.

13. The electronic device of claim 11, wherein:
a first separation distance between the window protection layer and the extension part of the frame is about 0.3 mm to about 0.7 mm.

14. The electronic device of claim 13, further comprising:
a lower plate supporting the display panel, wherein the lower plate is spaced apart from the protrusion part of the frame in the second direction.

15. The electronic device of claim 14, wherein:
a second separation distance is measured between the protrusion part and the lower plate in the second direction, and
wherein a ratio of the first separation distance to the second separation distance is about 0.8 to about 1.2.

16. The electronic device of claim 14, further comprising:
a panel protection film disposed between the display panel and the lower plate.

17. The electronic device of claim 11, further comprising:
a second cover layer disposed on and covering at least a portion of a bottom surface of the glass layer.

18. The electronic device of claim 17, wherein:
the second cover layer is spaced apart from the protrusion part of the frame in the first direction.

19. The electronic device of claim 11, wherein the first cover layer comprises:
a first folded part folded toward the glass layer, and
a second folded part folded from the first folded part toward a bottom surface of the glass layer and covers at least a portion of the bottom surface of the glass layer.

20. An electronic device, comprising:
a display device comprising:
a lower plate,
a display panel disposed on the lower plate, and
a window protection layer disposed on the display panel, wherein the lower plate, the display panel, and the window protection layer are sequentially stacked in a first direction; and
a frame accommodating the display device, wherein the frame comprises:
an extension part disposed along an outer periphery of the display device and extending in the first direction, and
a protrusion part protruding from the extension part in a second direction crossing the first direction,
wherein a first separation distance is measured between the protrusion part and the lower plate in the second direction,
wherein a second separation distance is measured between the extension part and the window protection layer in the second direction,
wherein a ratio of the second separation distance to the first separation distance is about 0.8 to about 1.2, and
wherein the second separation distance is about 0.3 mm to about 0.7 mm.
